(19) United States
(12) Patent Application Publication
(10) Pub. No.: US 2026/0039283 A1
(43) Pub. Date: Feb. 5, 2026

(54) DIGITAL PHASE CIRCUIT

(71) Applicant: Winbond Electronics Corp., Taichung City (TW)

(72) Inventor: Yu-Wei Hu, Hsinchu County (TW)

(73) Assignee: Winbond Electronics Corp., Taichung City (TW)

(21) Appl. No.: 19/173,832

(22) Filed: Apr. 9, 2025

(30) Foreign Application Priority Data
Jul. 30, 2024 (TW) 113128250

(51) Int. Cl. H03K 5/135; H03K 5/131; H03K 21/08

(52) U.S. Cl. CPC H03K 5/135; H03K 5/131; H03K 21/08

(57) ABSTRACT

A digital phase circuit is provided. The digital phase circuit includes a first inverter to a fourth inverter. The first inverter to the fourth inverter are connected in series to form an inverter ring, wherein an output end of the first inverter provides a first clock signal, an output end of the second inverter provides a second clock signal, an output end of the third inverter provides a third clock signal, and an output end of the fourth inverter provides a fourth clock signal. In particular, the first inverter and the third inverter are operated in one of a high impedance mode and a normal mode. At the same time, the second inverter and the fourth inverter are operated in the other of the high impedance mode and the normal mode.

### CROSS-REFERENCE TO RELATED APPLICATION

This application claims the priority benefit of Taiwan application serial no. 113128250, filed on Jul. 30, 2024. The entirety of the above-mentioned patent application is hereby incorporated by reference herein and made a part of this specification.

### BACKGROUND OF THE INVENTION

### Field of the Invention

The invention relates to a phase generating circuit, and in particular to a digital phase circuit.

### Description of Related Art

At present, the computer standard system main memory is a double data rate synchronous dynamic random-access memory (DDR SDRAM) device, and the DDR SDRAM generates the four internal clock signals needed for operation using an interval oscillator (CKT) or a clock oscillator. However, such four-phase generators are usually designed using an analog circuit, and analog four-phase generators usually require greater power consumption. The current digital phase generator solves the issue of power consumption, but the traditional digital four-phase generator not only has jitter issues during high-speed operation, but also has the issue of four-phase misalignment.

### SUMMARY OF THE INVENTION

The invention provides a digital phase circuit that may reduce jitter of a clock signal and alleviate the issue of phase misalignment of an internal clock signal.

A digital phase circuit of the invention includes a first inverter to a fourth inverter. The first inverter to the fourth inverter are connected in series to form an inverter ring, wherein an output end of the first inverter provides a first clock signal, an output end of the second inverter provides a second clock signal, an output end of the third inverter provides a third clock signal, and an output end of the fourth inverter provides a fourth clock signal. In particular, the first inverter and the third inverter are operated in one of a high impedance mode and a normal mode. At the same time, the second inverter and the fourth inverter are operated in the other of the high impedance mode and the normal mode.

Based on the above, in the digital phase circuit of an embodiment of the invention, the first inverter and the third inverter are operated in one of the high impedance mode and the normal mode, and at the same time the second inverter and the fourth inverter are operated in the other of the high impedance mode and the normal mode, so that the inverter ring formed by connecting the first inverter to the fourth inverter in series is operated in the manner of a frequency divider. Thereby, the inverter ring may reduce jitter and degree of misalignment of the first clock signal to the fourth clock signal, and further improve the performance of a double data rate synchronous dynamic random-access memory device.

In order to make the aforementioned features and advantages of the disclosure more comprehensible, embodiments accompanied with figures are described in detail below.

### BRIEF DESCRIPTION OF THE DRAWINGS

FIG. 1 is a circuit schematic diagram of a digital phase circuit according to an embodiment of the invention.

FIG. 2 is a schematic diagram of a clock waveform of a digital phase circuit according to an embodiment of the invention.

### DESCRIPTION OF THE EMBODIMENTS

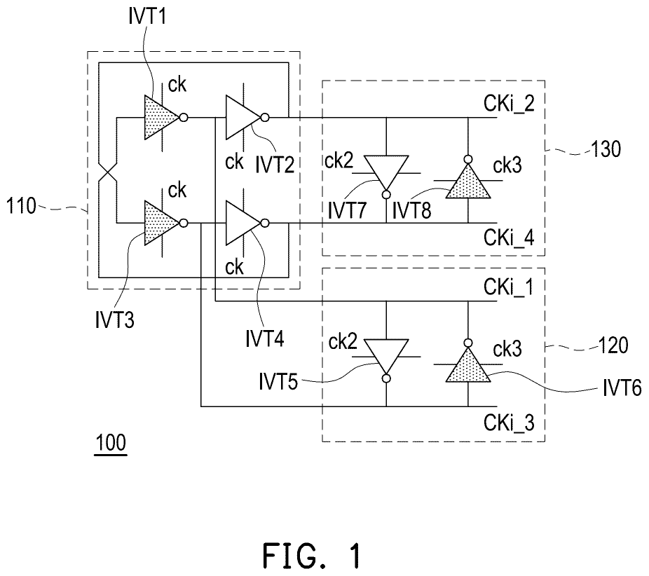

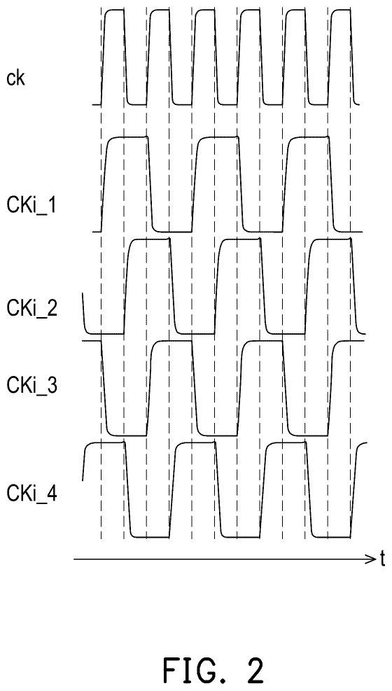

FIG. 1 is a circuit schematic diagram of a digital phase circuit according to an embodiment of the invention. FIG. 2 is a schematic diagram of a clock waveform of a digital phase circuit according to an embodiment of the invention. Please refer to FIG. 1 and FIG. 2. In an embodiment of the invention, a digital phase circuit 100 may be applied to a double data rate synchronous dynamic random-access memory (DDR SDRAM) device (including low power DDR SDRAM, graphics DDR SDRAM), to generate four internal phase clock signals (such as a first clock signal CKi_1 to a fourth clock signal CKi_4) for commanding the latch in the memory or outputting a clock signal.

Please refer to FIG. 1. In the present embodiment, the digital phase circuit 100 may be applied in a DDR SDRAM device, and the digital phase circuit 100 includes an inverter ring 110, a first latch circuit 120, and a second latch circuit 130.

The inverter ring 110 receives a first control signal ck and generates the first clock signal CKi_1 to the fourth clock signal CKi_4 with uniform phase shifts based on the first control signal ck, and the first latch circuit 120 is coupled to the first clock signal CKi_1 and the third clock signal CKi_3 to latch the first clock signal CKi_1 and the third clock signal CKi_3 and accelerate the transition states of the first clock signal CKi_1 and the third clock signal CKi_3, and the second latch circuit 130 is coupled to the second clock signal CKi_2 and the fourth clock signal CKi_4 to latch the second clock signal CKi_2 and the fourth clock signal CKi_4 and accelerate the transition states of the second clock signal CKi_2 and the fourth clock signal CKi_4.

In the present embodiment, the inverter ring 110 includes a first inverter IVT1 to a fourth inverter IVT4, wherein the first inverter IVT1 to the fourth inverter IVT4 are connected in series to form the inverter ring 110. The input end of the first inverter IVT1 is coupled to the output end of the fourth inverter IVT4, and the output end of the first inverter IVT1 provides the first clock signal CKi_1. The input end of the second inverter IVT2 is coupled to the output end of the first inverter IVT1, and the output end of the second inverter IVT2 provides the second clock signal CKi_2. The input end of the third inverter IVT3 is coupled to the output end of the second inverter IVT2, and the output end of the third inverter IVT3 provides the third clock signal CKi_3. The input end of the fourth inverter IVT4 is coupled to the output end of the third inverter IVT3, and the output end of the fourth inverter IVT4 provides the fourth clock signal CKi_4.

The first inverter IVT1 and the third inverter IVT3 are operated in one of a high impedance mode and a normal mode. At the same time, the second inverter IVT2 and the fourth inverter IVT4 are operated in the other of the high impedance mode and the normal mode. When the first inverter IVT1 to the fourth inverter IVT4 are operated in the high impedance mode, the input ends and the output ends of the first inverter IVT1 to the fourth inverter IVT4 are in a floating state; when the first inverter IVT1 to the fourth inverter IVT4 are operated in the normal mode, the input ends and the output ends of the first inverter IVT1 to the fourth inverter IVT4 are in the inverted state. That is, the state transition of the voltage of the output end occurs in response to the state transition of the voltage of the input end.

Based on the above, via the first inverter IVT1 and the third inverter IVT3 operating in one of the high impedance mode and the normal mode, and at the same time, the second inverter IVT2 and the fourth inverter IVT4 operating in the other of the high impedance mode and the normal mode, the inverter ring 110 is operated in the manner of a divider to reduce jitter and degree of misalignment of the first clock signal CKi_1 to the fourth clock signal CKi_4, so as to further improve the performance of the DDRS DRAM device.

In an embodiment of the invention, the first inverter IVT1 to the fourth inverter to IVT4 receive the first control signal ck to be operated in the high impedance mode or the normal mode based on the first control signal ck. In particular, the first control signal ck may be a reference clock signal, and therefore the inverter ring 110 may divide the reference clock signal to generate the first clock signal CKi_1 to the fourth clock signal CKi_4.

In an embodiment of the invention, the positive power ends of the first inverter IVT1 and the third inverter IVT3 may receive the first control signal ck, and the negative power ends of the first inverter IVT1 and the third inverter IVT3 may receive the inverted signal or the low voltage level of the first control signal ck. Moreover, the positive power ends of the second inverter IVT2 and the fourth inverter IVT4 receive the inverted signal or the high voltage level of the first control signal ck, and the negative power ends of the second inverter IVT2 and the fourth inverter IVT4 receive the first control signal ck.

In an embodiment of the invention, the first latch circuit 120 receives the second control signal ck2 and the third control signal ck3 to latch the first clock signal CKi_1 and the third clock signal CKi_3 based on the second control signal ck2 and the third control signal ck3. Moreover, the second latch circuit 130 receives the second control signal ck2 and the third control signal ck3 to latch the second clock signal CKi_2 and the fourth clock signal CKi_4 based on the second control signal ck2 and the third control signal ck3.

In an embodiment of the invention, the second control signal ck2 and the third control signal ck3 are used to control the first latch circuit 120 and the second latch circuit 130 to latch the level or accelerate the transition state of the level. For example, the second control signal ck2 may enable latching the levels of the first clock signal CKi_1 to the fourth clock signal CKi_4, and may be enabled when the levels of the third clock signal CKi_3 and the fourth clock signal CKi_4 are raised; the third control signal ck2 may enable latching the levels of the first clock signal CKi_1 to the fourth clock signal CKi_4, and may be enabled when the levels of the first clock signal CKi_1 and the second clock signal CKi_2 are raised. Based on the above, in an embodiment of the invention, the second control signal ck2 may be different from the third control signal ck3.

In an embodiment of the invention, the first latch circuit 120 includes a fifth inverter IVT5 and a sixth inverter IVT6. The fifth inverter IVT5 has an input end receiving the first clock signal CKi_1, a positive power end receiving the second control signal ck2, and an output end coupled to the third clock signal CKi_3, wherein the negative power end of the fifth inverter IVT5 may receive the inverted signal or the low voltage level of the second control signal ck2. The sixth inverter IVT6 has an input end receiving the third clock signal CKi_3, a positive power end receiving the third control signal ck3, and an output end coupled to the first clock signal CKi_1, wherein the negative power end of the sixth inverter IVT6 may receive the inverted signal or the low voltage level of the third control signal ck3.

In an embodiment of the invention, the second latch circuit 130 includes a seventh inverter IVT7 and an eighth inverter IVT8. The seventh inverter IVT7 has an input end receiving the second clock signal CKi_2, a positive power end receiving the second control signal ck2, and an output end coupled to the fourth clock signal CKi_4, wherein the negative power end of the seventh inverter IVT7 may receive the inverted signal or the low voltage level of the second control signal ck2. The eighth inverter IVT8 has an input end receiving the fourth clock signal CKi_4, a positive power end receiving the third control signal ck3, and an output end coupled to the second clock signal CKi_2, wherein the negative power end of the eighth inverter IVT8 may receive the inverted signal or the low voltage level of the third control signal ck3.

Based on the above, in the digital phase circuit of an embodiment of the invention, the first inverter and the third inverter are operated in one of the high impedance mode and the normal mode, and at the same time the second inverter and the fourth inverter are operated in the other of the high impedance mode and the normal mode, so that the inverter ring formed by connecting the first inverter to the fourth inverter in series is operated in the manner of a frequency divider. Thereby, the inverter ring may reduce jitter and degree of misalignment of the first clock signal to the fourth clock signal, and further improve the performance of the DDRS DRAM device.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A digital phase circuit, comprising:
a first inverter to a fourth inverter connected in series to form an inverter ring, wherein an output end of the first inverter provides a first clock signal, an output end of the second inverter provides a second clock signal, an output end of the third inverter provides a third clock signal, and an output end of the fourth inverter provides a fourth clock signal,
wherein the first inverter and the third inverter are operated in one of a high impedance mode and a normal mode, and at the same time, the second inverter and the fourth inverter are operated in the other of the high impedance mode and the normal mode.

2. The digital phase circuit of claim 1, wherein the first inverter to the fourth inverter receive a first control signal to be operated in the high impedance mode or the normal mode based on the first control signal.

3. The digital phase circuit of claim 2, wherein:
positive power ends of the first inverter and the third inverter receive the first control signal, and
negative power ends of the second inverter and the fourth inverter receive the first control signal.

4. The digital phase circuit of claim 3, further comprising:
a first latch circuit receiving a second control signal and a third control signal to latch the first clock signal and the third clock signal based on the second control signal and the third control signal; and
a second latch circuit receiving the second control signal and the third control signal to latch the second clock signal and the fourth clock signal based on the second control signal and the third control signal.

5. The digital phase circuit of claim 4, wherein the first latch circuit comprises:
a fifth inverter having an input end receiving the first clock signal, a positive power end receiving the second control signal, and an output end coupled to the third clock signal; and
a sixth inverter having an input end receiving the third clock signal, a positive power end receiving the third control signal, and an output end coupled to the first clock signal.

6. The digital phase circuit of claim 4, wherein the second latch circuit comprises:
a seventh inverter having an input end receiving the second clock signal, a positive power end receiving the second control signal, and an output end coupled to the fourth clock signal; and
an eighth inverter having an input end receiving the fourth clock signal, a positive power end receiving the third control signal, and an output end coupled to the second clock signal.

7. The digital phase circuit of claim 4, wherein the second control signal is different from the third control signal.

8. The digital phase circuit of claim 2, wherein the first control signal is a reference clock signal.

9. The digital phase circuit of claim 8, wherein the inverter ring divides the reference clock signal to generate the first clock signal to the fourth clock signal.
